(19) United States
(12) Patent Application Publication
(10) Pub. No.: US 2006/0115967 A1
(43) Pub. Date: Jun. 1, 2006

(54) Methods of manufacturing a semiconductor device

(75) Inventors: Hee-Sook Park, Seoul (KR); Gil-Heyun Choi, Gyeonggi-do (KR); Chang-Won Lee, Gyeonggi-do (KR); Byung-Hak Lee, Gyeonggi-do (KR); Jong-Ryeol Yoo, Gyeonggi-do (KR); Dong-Chan Lim, Seoul (KR); Jae-Hwa Park, Gyeonggi-do (KR); Sun-Pil Youn, Seoul (KR); Woong-Hee Sohn, Gyeonggi-do (KR)

Correspondence Address: MYERS BIGEL SIBLEY & SAJOVEC, PO BOX 37428, RALEIGH, NC, 27627, US

(73) Assignee: Samsung Electronic Co., Ltd.

(21) Appl. No.: 11/246,791

(22) Filed: Oct. 7, 2005

(30) Foreign Application Priority Data
Oct. 7, 2004 (KR) 10-2004-0080001

(51) Int. Cl. H01L 21/8238; H01L 21/425

(52) U.S. Cl. 438/514; 438/199; 438/530

(57) ABSTRACT

In a method of manufacturing a semiconductor device including a polysilicon layer on which a heat treatment is performed in hydrogen atmosphere, a preliminary polysilicon layer is formed on a semiconductor substrate. Fluorine (F) impurities are implanted onto the preliminary polysilicon layer, so that the preliminary polysilicon layer is formed into a polysilicon layer. A main heat treatment is performed on the polysilicon layer, thereby preventing a void caused by the fluorine (F) in the polysilicon layer. A subsidiary heat treatment is further performed on the polysilicon layer prior to the main heat treatment, thereby activating dopants in the polysilicon layer. Electrical characteristics and performance of a semiconductor device are improved since the void is sufficiently prevented in the polysilicon layer.

### CROSS-REFERENCE TO RELATED APPLICATION

This application claims priority under 35 USC § 119 to Korean Patent Application No. 10-2004-80001 filed on Oct. 7, 2004, the content of which is herein incorporated by reference in its entirety.

### FIELD OF THE INVENTION

The present invention relates to methods of manufacturing a semiconductor device. More particularly, the present invention relates to methods of manufacturing a semiconductor device involving a hydrogen annealing process.

### BACKGROUND OF THE INVENTION

In general, a polysilicon layer for a gate electrode in a semiconductor device may be doped with N type impurities regardless of P type metal oxide silicon (PMOS) and N type metal oxide silicon (NMOS) transistors. Hereinafter, a polysilicon layer doped with N type impurities is referred to as an N type polysilicon layer, and a polysilicon layer doped with P type impurities is referred to as a P type polysilicon layer. However, when the N type polysilicon layer is used as a gate electrode for a PMOS transistor, a threshold voltage of the PMOS transistor may be relatively high due to a buried channel, thereby increasing power consumption. Accordingly, such a PMOS transistor may not satisfy recent requirements of dynamic random access memory (DRAM) devices which require lower operation voltage and a high performance.

Thus, typically a gate electrode of a PMOS transistor may comprise a P type polysilicon layer, and a gate electrode of an NMOS transistor may comprise an N type polysilicon layer.

An N type polysilicon layer of a gate electrode of a PMOS transistor may be transformed into a P type polysilicon layer by excessive doping with boron (B) onto the N type polysilicon layer. However, the diffusion speed of boron (B) may be very high, so that boron (B) may be infiltrated into a silicon substrate through a gate oxide layer in a subsequent heat treatment, thereby deteriorating the gate oxide layer.

It has been suggested that impurities including fluorine (F), such as boron fluoride (BF₂) ions, can be doped into the polysilicon layer in a PMOS region so as to reduce the diffusion speed of boron (B). However, the fluorine ions may cause a void, such as a hole, at surface portions of the polysilicon layer. Particularly, the void may be enlarged into a size over about 100 nm when a thickness of the polysilicon layer is no less than about 100 Å. It is possible that the void in the polysilicon layer generally can cause an electrical connection failure between the polysilicon layer and a conductive layer formed on the polysilicon layer. Furthermore, when the void is further enlarged, the conductive layer on the polysilicon layer may be lifted from the polysilicon layer, so that the conductive layer may be separated from the polysilicon layer.

The fluorine ions, which may also cause a void in the polysilicon layer, can also be included in the conductive layer. Methods of removing fluorine ions in the conductive layer have been proposed such as in Korean Patent Laid-Open Publication Nos. 2002-2561 and 2003-50652. However, the void in the polysilicon layer may remain even though the fluorine ions are removed by the same method in the above Korean patent publications.

### SUMMARY OF THE INVENTION

Accordingly, the present invention provides methods of manufacturing semiconductor devices in which voids in the polysilicon layer are efficiently removed.

In some embodiments of the present invention, there is provided a method of manufacturing a semiconductor device. A preliminary polysilicon layer is formed on a semiconductor substrate, and fluorine impurities are implanted onto the preliminary polysilicon layer, so that the preliminary polysilicon layer is formed into a polysilicon layer. A main heat treatment is performed on the polysilicon layer, thereby reducing and/or preventing a void caused by the fluorine (F) in the polysilicon layer.

According to some other embodiments of the present invention, there is provided another method of manufacturing a semiconductor device. A gate oxide layer is formed on a semiconductor substrate on which a PMOS region and an NMOS region are defined. A first polysilicon layer is formed on the gate oxide layer of the PMOS region and a second polysilicon layer is formed on the gate oxide layer of the NMOS region. The first polysilicon layer is doped with impurities comprising boron (B) and fluorine (F), and the second polysilicon layer is doped with impurities without boron (B) and fluorine (F). A main heat treatment is performed on the first and second polysilicon layers, thereby activating dopants in the first and second polysilicon layers and preventing a void caused by the fluorine (F) in the first polysilicon layer. A conductive layer is formed on the first and second polysilicon layers after the main heat treatment. The gate oxide layer, the first and second polysilicon layers and the conductive layer are sequentially etched away, thereby forming a first gate structure in the PMOS region and a second gate structure in the NMOS region. The first gate structure comprises a gate oxide pattern, a first polysilicon pattern and a conductive pattern sequentially stacked on the substrate in the PMOS region, and the second gate structure comprises a gate oxide pattern, a second polysilicon pattern and a conductive pattern sequentially stacked on the substrate in the NMOS region.

According to additional embodiments of the present invention, a heat treatment performed in an ambient hydrogen atmosphere reduces the fluorine concentration in the polysilicon layer, thereby preventing voids in the polysilicon layer. Electrical characteristics and/or performance of a semiconductor device are improved since the void is sufficiently reduced and/or prevented in the polysilicon layer.

### BRIEF DESCRIPTION OF THE DRAWINGS

FIGS. 1 to 5 are cross sectional views illustrating processing steps for a method of manufacturing a semiconductor device according to some embodiments of the present invention;

FIGS. 6 to 11 are views illustrating processing steps for a method of manufacturing a semiconductor device according to some embodiments of the present invention;

FIG. 12 provide pictures of a conventional polysilicon layer taken by a scanning electron microscope (SEM);

FIG. 13 provide SEM pictures of a polysilicon layer according to some embodiments of the present invention; and

FIG. 14 is a graph of fluorine concentration in the polysilicon layer in accordance with a thickness of the polysilicon layer measured by a secondary ion mass spectrometer (SIMS).

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

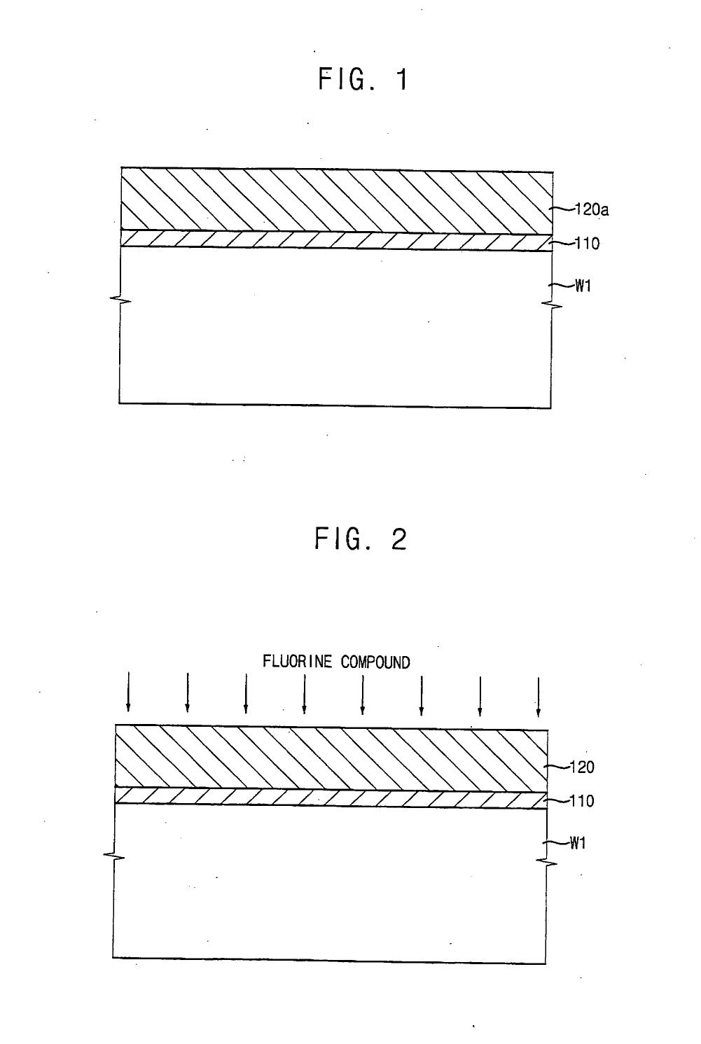

Embodiments of the present invention provide methods of manufacturing a semiconductor device. In particular, FIGS. 1 to 5 are cross sectional views illustrating processing steps for a method of manufacturing a semiconductor device according to some embodiments of the present invention.

Referring to FIG. 1, a gate oxide layer 110 is formed on a semiconductor substrate W1, such as a wafer, through a thermal oxidation process, and a preliminary polysilicon layer 120a is formed on the gate oxide layer 110. The gate oxide layer 110 has a sufficient thickness to prevent dopants in a polysilicon layer 120 in FIG. 2 from infiltrating into the substrate W1. The preliminary polysilicon layer 120a may include a polysilicon layer doped with N type impurities such as phosphorus (P) and/or arsenic (As) or may be a pure polysilicon layer.

Referring to FIG. 2, the preliminary polysilicon layer 120a (as shown in FIG. 1) is doped with fluorine impurities thereby forming a polysilicon layer 120. In some embodiments, the fluorine impurities may include fluorine compound ions such as boron difluoride (BF₂) ions, and are implanted into the preliminary polysilicon layer 120a at a dose of no less than about 10¹⁵ atoms/cm², and more particularly, at a dose in a range from about 10¹⁵ atoms/cm² to about 10²¹ atoms/cm².

Fluoride ions are combined with each other in the polysilicon layer 120, thereby being converted into fluorine gas (F₂). If the fluorine gas (F₂) is not exhausted from the polysilicon layer 120, a void can be caused in the polysilicon layer 120. The void in the polysilicon layer 120 may deteriorate electrical characteristics of the polysilicon layer 120, and may cause an electrical connection failure between the polysilicon layer and a conductive layer formed on the polysilicon layer in a subsequent process.

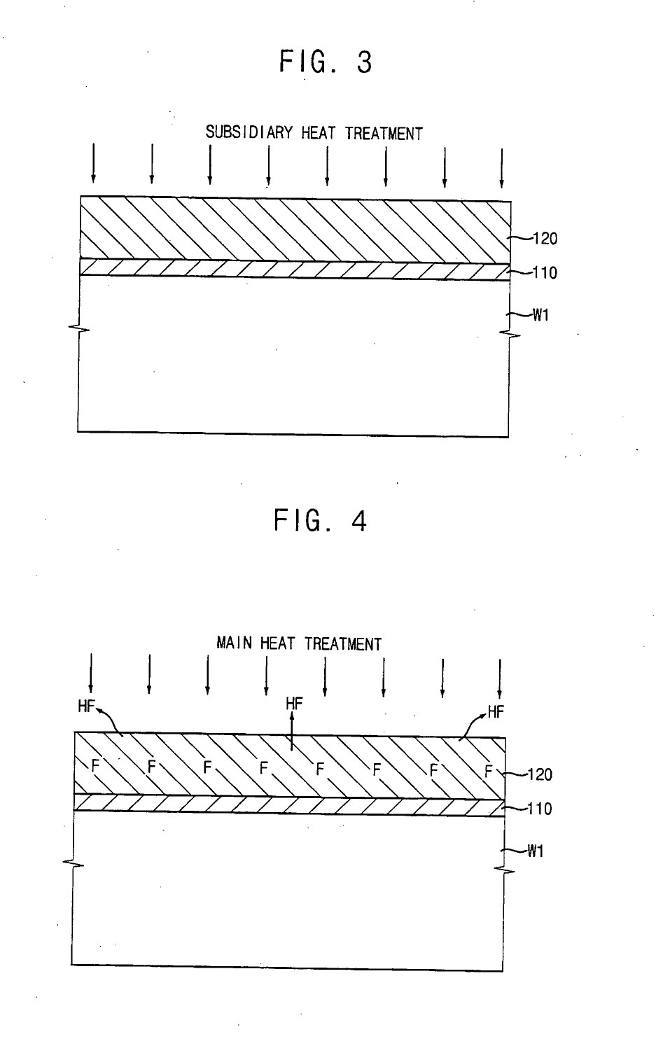

Referring to FIG. 3, a subsidiary heat treatment is performed on the polysilicon layer 120 doped with a fluorine compound, so that dopants in the polysilicon layer 120 are electrically activated. When the subsidiary heat treatment is performed at a temperature below about 400° C., the dopants in the polysilicon layer 120 may not be electrically activated. When the subsidiary heat treatment is performed at a temperature over about 1200° C., the polysilicon layer 120 may be melted down and the dopants in the polysilicon layer 120 may be rapidly diffused due to excessive heat, thereby generating a thermal budget and/or deteriorating electrical characteristics of a semiconductor device. Accordingly, the subsidiary heat treatment is performed at a temperature in a range of from about 400° C. to about 1200° C., and particularly, in some embodiments, in a range of from about 900° C. to about 950° C. The subsidiary heat treatment may be performed under an ambient gas such as an inactive gas. Examples of the inactive gas include, but not limited to, nitrogen (N₂) gas, ammonia (NH3) gas or argon (Ar) gas. These inactive gases can be used alone or in combinations thereof.

The subsidiary heat treatment is often performed at the above temperature range in an ambient of a vacuum. The subsidiary heat treatment may include a rapid thermal process (RTP), a spike RTP (SRTP) and a furnace heat treatment, the selection of the heat treatment process being within the skill of one in the art.

Referring to FIG. 4, a main heat treatment is performed on the polysilicon layer 120 doped with a fluorine compound at a temperature in a range of about 400° C. to about 1200° C. In some embodiments, the pressure is in the range of about 0.01 Torr to about 760 Torr and hydrogen gas (H₂) may be used. The hydrogen gas (H₂) may be supplied at a flow rate in a range of about 1 sccm to about 500,000 sccm. The main heat treatment may prevent the void and electrically activates dopants in the polysilicon layer 120. Fluorine ions in the polysilicon layer are reacted with hydrogen (H) ions during the main heat treatment, thereby being converted into hydrogen fluoride (HF). The hydrogen fluoride (HF) is diffused out from the polysilicon layer 120, thereby removing the void from the polysilicon layer 120. In addition, an argon plasma treatment may be further performed on the polysilicon layer 120 in an ambient hydrogen atmosphere, so that the fluorine ions in the polysilicon layer 120 can also be removed as hydrogen fluoride (HF) gas.

According to some embodiments of the present invention, a conductive layer is formed on the polysilicon layer 120 on which the main heat treatment is performed through a known process such as a chemical vapor deposition (CVD) process. The conductive layer may include a metal or metal compound. Examples of the metal or metal compound may include tungsten nitride (WN), tungsten (W), tantalum nitride (TaN), tantalum (Ta), tungsten silicon (WSi), cobalt silicon (CoSi2), etc. These metal and/or metal compounds can be used alone or in combinations thereof.

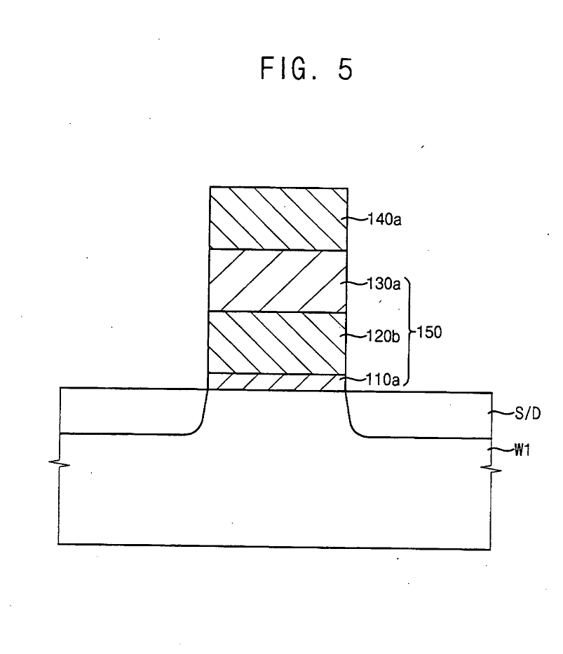

Referring to FIG. 5, a hard mask pattern 140a is formed on the conductive layer, and is comprised of a nitride-based material. Examples of the nitride-based material include a silicon nitride (SiN), silicon oxynitride (SiON), etc. These nitride-based materials can be used alone or in combinations thereof.

The conductive layer, the polysilicon layer 120 and the gate oxide layer 110 are sequentially etched away using the hard mask pattern 140a as an etching mask, thereby forming a conductive pattern 130a, a polysilicon pattern 120b and a gate oxide pattern 110a sequentially stacked on the substrate W1. Accordingly, a gate structure 150 is formed including the conductive pattern 130a, the polysilicon pattern 120b and the gate oxide pattern 110a. Impurities are implanted onto surface portions of the substrate W1 using the gate structure 150 as an implantation mask, thereby forming source/drain regions at the surface portions of the substrate W1 adjacent to the gate structure 150. The source/drain regions of the substrate W1 are doped with P type impurities and the polysilicon pattern 120b is doped with P type impurities such as boron (B). Accordingly, a semiconductor device including the gate structure 150 may be utilized as a PMOS transistor of which electrical characteristics are improved due to a surface channel thereof.

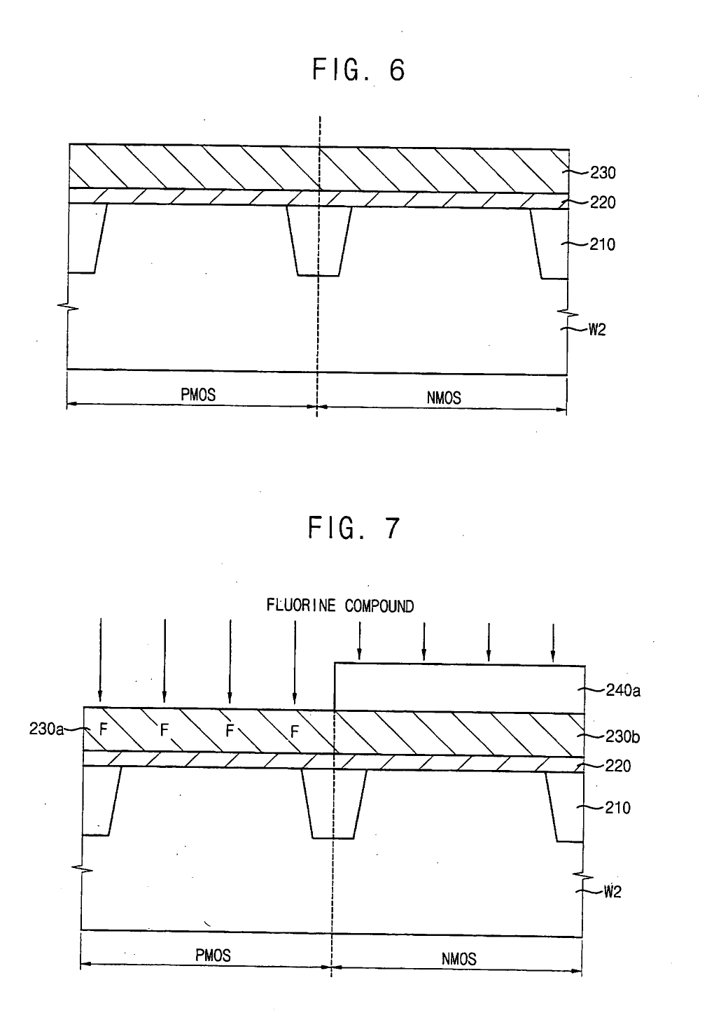

FIGS. 6 to 11 are views illustrating processing steps for methods of manufacturing a semiconductor device according to some embodiments of the present invention.

Referring to FIG. 6, an isolation layer 210 for separating conductive structures on a substrate (hereinafter, referred to as a device isolation layer) is formed on a semiconductor substrate W2 such as a wafer, so that an NMOS region and a PMOS region are defined on the substrate W2. In some embodiments, a trench (not shown) is formed on the substrate W1 through a shallow-trench isolation (STI) process, and insulation material is filled into the trench, thereby forming the device isolation layer 210 on the substrate W2.

A gate oxide layer 220 is formed on the substrate W2 on which the PMOS region and the NMOS region are defined. The gate oxide layer 220 is the same as described previously, so any further description concerning the gate oxide layer 220 will be omitted. A polysilicon layer 230 is formed on the gate oxide layer 220. The polysilicon layer 230 may include a polysilicon layer doped with N type impurities such as phosphorus (P) and arsenic (As) or a pure polysilicon layer.

Referring to FIG. 7, the polysilicon layer 230 is divided into first and second polysilicon layers 230a and 230b on the substrate W2. That is, the polysilicon layer 230 on the PMOS region is referred to as the first polysilicon layer 230a, and the polysilicon layer 230 on the NMOS region is referred to as the second polysilicon layer 230b. A photoresist pattern 240a is formed on the second polysilicon layer 230b, so that the first polysilicon layer 230a is exposed through the photoresist pattern 240a. Impurities comprising boron (B) and fluorine (F) are implanted onto the first polysilicon layer 230a and the photoresist pattern 240a, so that only the first polysilicon layer 230a is doped with the impurities. In some embodiments, boron difluoride (BF₂) may be used to provide the impurities. A flow rate of the impurities comprising boron (B) and fluorine (F) is the same as the flow rate of the fluorine impurities, so any further detailed description on the flow rate will be omitted hereinafter. The photoresist pattern 240a is removed through an ashing process and/or a strip process after the doping process is completed.

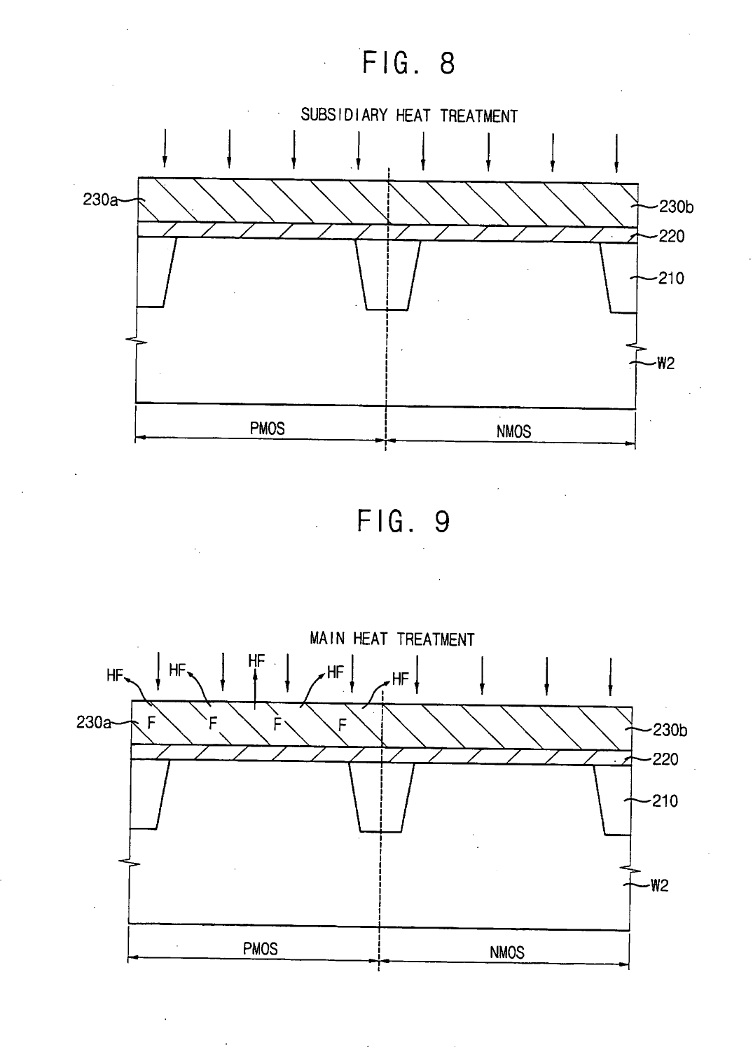

Referring to FIG. 8, a subsidiary heat treatment is performed on the first and second polysilicon layers 230a and 230b, so that dopants in the first and second polysilicon layers 230a and 230b are electrically activated. The subsidiary heat treatment is the same as described above, so any further detailed description on the subsidiary heat treatment is omitted.

Referring to FIG. 9, a main heat treatment is performed on the first and second polysilicon layers 230a and 230b in an ambient hydrogen atmosphere. The main heat treatment is performed under the same conditions as described previously, so that dopants in the first and second polysilicon layers 230a and 230b are electrically activated and the void in the first polysilicon layer is sufficiently reduced and/or prevented. The doped fluorine ions are combined with each other in the first polysilicon layer 230a, and fluorine gas is generated in the first polysilicon layer 230a. The fluorine gas contributes to the void in the first polysilicon layer 230a. The removal mechanism of the fluorine gas is the same as described above. In addition to the main heat treatment, an argon plasma treatment may be further performed on the first polysilicon layer 230a in an ambient hydrogen atmosphere, so that the fluorine ions in the first polysilicon layer 230a are also removed as hydrogen fluoride (HF) gas. Accordingly, the first polysilicon layer 230a from which the fluorine ions are removed is doped with P type impurities such as boron (B), so that the first polysilicon layer 230a is used as a gate structure of a surface channel type PMOS transistor.

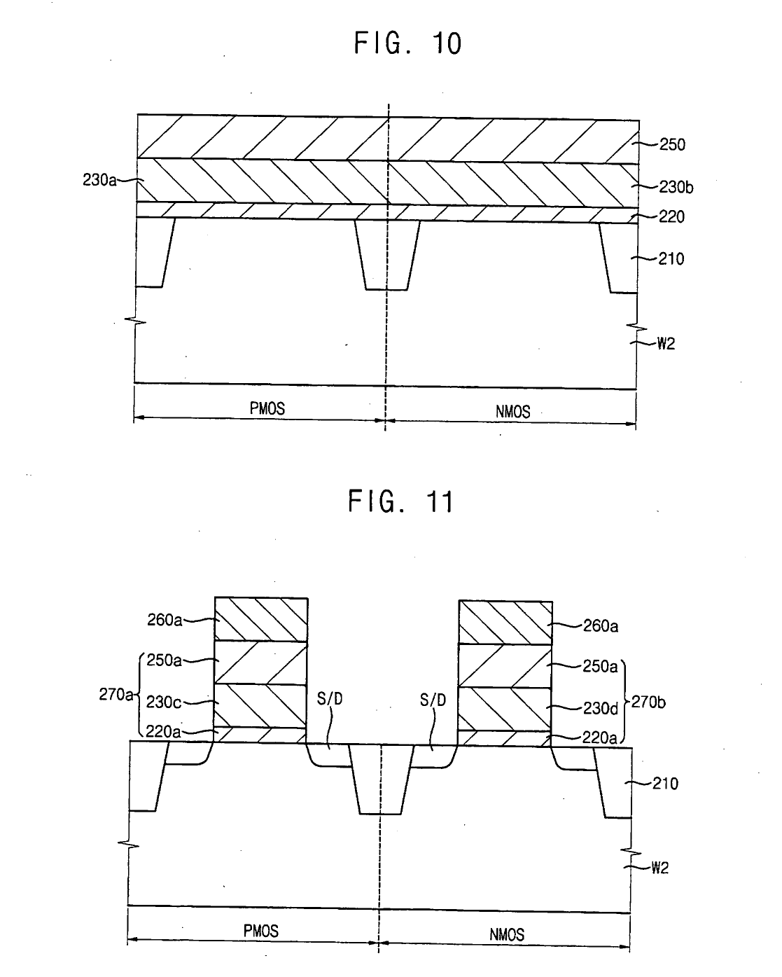

Referring to FIG. 10, a conductive layer 250 is formed on the polysilicon layer 230 on which the main heat treatment is performed through a chemical vapor deposition (CVD) process. The conductive layer may include a metal or metal compound. Examples of the metal or metal compound include tungsten nitride (WN), tungsten (W), tantalum nitride (TaN), tantalum (Ta), tungsten silicon (WSi), cobalt silicon (CoSi2), etc. These metal and/or metal compounds can be used alone or in combinations thereof.

Referring to FIG. 11, a hard mask pattern 260a is formed on the conductive layer 250 as described above. The conductive layer 250, the first and second polysilicon layers 230a and 230b and the gate oxide layer 220 are sequentially etched away using the hard mask pattern 260a as an etching mask, thereby forming a conductive pattern 250a, first and second polysilicon patterns 230c and 230d and a gate oxide pattern 220a sequentially stacked on the substrate W2. Accordingly, a first gate structure 270a is formed on the PMOS region of the substrate W2 to have the conductive pattern 250a, the first polysilicon pattern 230c and the gate oxide pattern 220a, and a second gate structure 270b is formed on the NMOS region of the substrate W2 to include the conductive pattern 250a, the second polysilicon pattern 230d and the gate oxide pattern 220a.

Impurities are implanted onto surface portions of the substrate W2 using the first and second gate structures 270a and 270b as an implantation mask, thereby forming P type source/drain regions at the surface portions of the PMOS regions of the substrate W1 adjacent to the first gate structure 270a and N type source/drain regions at the surface portions of the NMOS regions of the substrate W2 adjacent to the second gate structure 270b. The P type source/drain regions of the substrate W2 are doped with P type impurities, and the N type source/drain regions of the substrate W2 are doped with N type impurities. Accordingly, a semiconductor device including the first gate structure 270a may be utilized as a PMOS transistor of which electrical characteristics are improved due to a surface channel thereof.

A gate oxide layer was formed on a semiconductor substrate and a polysilicon layer was formed on the gate oxide layer. Boron difluoride ions were doped into the polysilicon layer at a dose of about 1.2×10¹⁵ atoms/cm² with energy of about 15 keV. A rapid thermal annealing (RTA) was performed at a temperature of about 900° C. on the polysilicon layer for activating the dopants in the polysilicon layer. Thereafter, the above conventionally doped polysilicon layer was estimated using a scanning electron microscope (SEM).

FIG. 12 shows pictures of a conventional polysilicon layer taken by a scanning electron microscope (SEM). As shown in FIG. 12, a void V was shown in the polysilicon layer. Particularly, the void was intensively shown in a depth region in the range of about 100 Å to about 200 Å from a top surface of the polysilicon layer, and a size of the void was no less than about 100 nm when the depth of the polysilicon layer was no less than about 100 Å. The estimation results confirm that the void is shown when the boron difluoride ions are implanted at a dose of no less than about 10¹⁵ atoms/cm².

In contrast, first, second and third heat treatments were sequentially performed on the polysilicon layer according to some embodiments of the invention. The first heat treatment was performed for two seconds at a temperature of about 900° C. and a pressure of about 80 Torr under the condition that hydrogen gas was supplied at a rate of about 20 standard liters per minute (slm). The second heat treatment was performed for two seconds at a temperature of about 900° C. and a pressure of about 40 Torr under the condition that hydrogen gas was supplied at a rate of about 40 slm, and the third heat treatment was performed for two seconds at a temperature of about 950° C. and a pressure of about 80 Torr under the condition that hydrogen gas was supplied at a rate of about 40 slm. Thereafter, the void removal of the polysilicon layer was evaluated using the SEM.

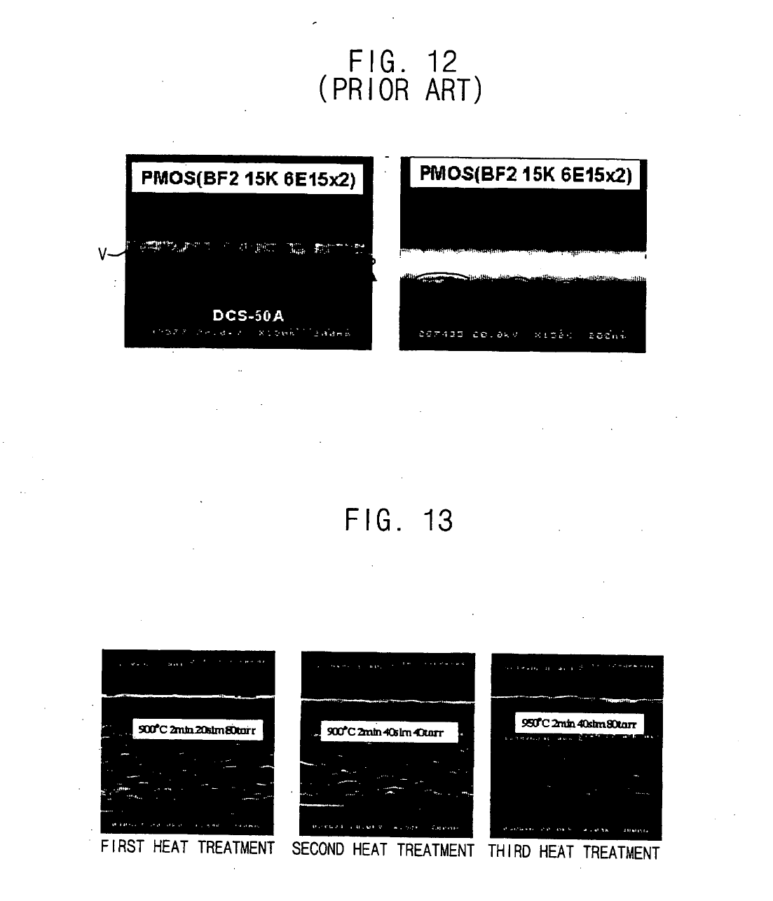

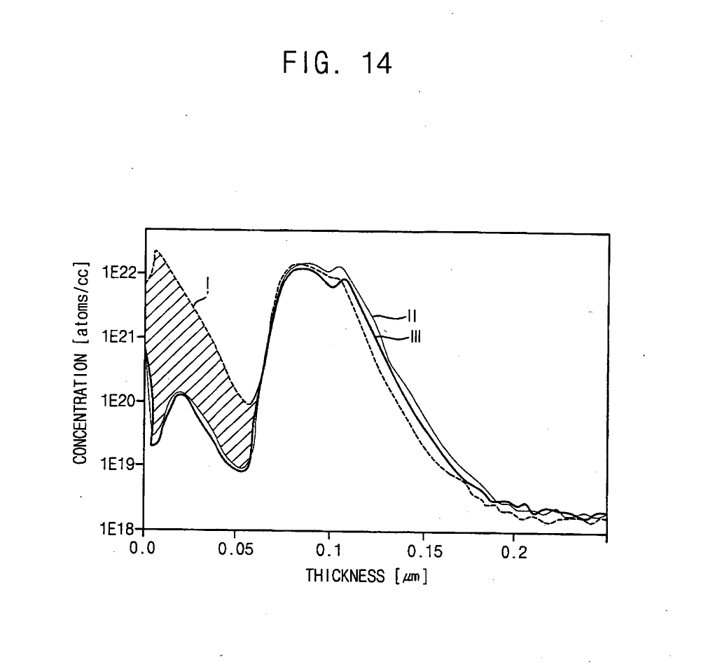

FIG. 13 shows SEM pictures of a polysilicon layer according to an exemplary embodiment of the present invention. As shown in FIG. 13, no void was shown in the polysilicon layer due to the first, second and third heat treatments.

However, when a rapid thermal nitridation (RTN) process, a speed ramping up process, a low temperature thermal oxidation process or an RTP at a high temperature of about 1000° C. was performed on the polysilicon layer in place of the RTP process performed in an ambient of hydrogen atmosphere, the void was confirmed are remaining in the polysilicon layer.

Accordingly, the above estimation results confirm that the RTP process in an ambient hydrogen atmosphere can remove the void in the polysilicon layer.

The above estimation results may also be more clearly confirmed by fluorine concentration in the polysilicon layer. FIG. 14 is a graph of fluorine concentration in the polysilicon layer in accordance with a thickness of the polysilicon layer measured by a secondary ion mass spectrometer (SIMS).

In FIG. 14, the graph, indicated as reference numeral I, shows the fluorine concentration in the conventional polysilicon layer, and the graphs indicated as reference numerals II and III, respectively, show the fluorine concentration in the polysilicon layer according to some embodiments of the present invention.

Particularly, boron fluoride ions were implanted onto a polysilicon layer for 30 seconds at a temperature of about 950° C. in nitrogen atmosphere, and an RTA was performed on the doped polysilicon layer, thereby forming the conventional doped polysilicon layer. Graph I in FIG. 14 shows the fluorine concentration of the conventional doped polysilicon layer. Boron fluoride ions were implanted onto a polysilicon layer in accordance with an exemplary embodiment of the present invention, and a first heat treatment was performed on the doped polysilicon layer for 2 minutes at a temperature of about 900° C. and at a pressure of about 80 Torr under the condition that hydrogen gas was supplied at a flow rate of about 60 slm, thereby forming a first doped polysilicon layer according to an exemplary embodiment of the present invention. Graph II in FIG. 14 shows the fluorine concentration of the first doped polysilicon layer according to an exemplary embodiment of the present invention. Boron fluoride ions were also implanted onto a polysilicon layer in accordance with an exemplary embodiment of the present invention, and a second heat treatment was performed on the doped polysilicon layer for 2 minutes at a temperature of about 900° C. and at a pressure of about 80 Torr under the condition that hydrogen gas was supplied at a flow rate of about 20 slm, thereby forming a second doped polysilicon layer according to an exemplary embodiment of the present invention. Graph III in FIG. 14 shows the fluorine concentration of the second doped polysilicon layer according to some embodiments of the present invention.

The graphs in FIG. 14 confirm that the heat treatment performed in hydrogen atmosphere reduces the fluorine concentration at a surface portion (hatched area in FIG. 14) of the polysilicon as compared with the conventional RTA. That is, the fluorine concentration in Graph II or Graph III is about 0.1 to about 0.001 times as high as the fluorine concentration in Graph I.

Accordingly, the fluorine ions, which contribute to the void in the polysilicon layer, are removed as hydrogen fluoride (HF) gas, so that there is a decreased possibility of void generation in the polysilicon layer.

As a result, a specific resistance of the polysilicon layer is sufficiently reduced since few voids remain in the polysilicon layer, thereby improving electrical characteristics of the semiconductor device. Furthermore, an electrical connection between the polysilicon layer and a conductive layer on the polysilicon layer is also reinforced.

According to some embodiments of the present invention, a heat treatment performed in hydrogen atmosphere remarkably reduces the fluorine concentration in the polysilicon layer, thereby reducing and/or preventing voids in the polysilicon layer. Electrical characteristics and/or performance of a semiconductor device are improved since the void is sufficiently reduced and/or prevented in the polysilicon layer.

Although exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. A method of manufacturing a semiconductor device, comprising:
forming a preliminary polysilicon layer on a semiconductor substrate;
implanting fluorine impurities onto the preliminary polysilicon layer, so that the preliminary polysilicon layer is converted into a polysilicon layer; and
performing a main heat treatment on the polysilicon layer at a temperature in a range of about 400° C. to about 1200° C. in an ambient hydrogen atmosphere, thereby reducing and/or preventing a void caused by the fluorine (F) in the polysilicon layer.

2. The method of claim 1, further comprising forming a gate oxide layer on the substrate.

3. The method of claim 1, prior to performing the main heat treatment, further comprising performing a subsidiary heat treatment on the polysilicon layer, thereby activating dopants in the polysilicon layer.

4. The method of claim 3, wherein the subsidiary heat treatment is performed at a temperature in the range of about 400° C. to about 1200° C. using one of nitrogen (N₂) gas, ammonia (NH₃) gas, or argon (Ar) gas or a mixture thereof.

5. The method of claim 3, wherein the subsidiary heat treatment is performed at the temperature in a range of about 400° C. to about 1200° C. in a vacuum atmosphere.

6. The method of claim 1, wherein the preliminary polysilicon layer is doped with phosphorus (P) and arsenic (As).

7. The method of claim 1, wherein the preliminary polysilicon layer comprises a pure polysilicon layer without impurities.

8. The method of claim 1, wherein the fluorine impurities further comprise boron (B).

9. The method of claim 1, wherein the fluorine impurities further comprise boron difluoride (BF₂) ions.

10. The method of claim 1, wherein the fluorine impurities including fluorine (F) are implanted onto the preliminary polysilicon layer at a dosage of about 10¹⁵ atoms/cm².

11. A method of manufacturing a semiconductor device, comprising:
forming a gate oxide layer on a semiconductor substrate on which a PMOS region and an NMOS region are defined;
forming a first polysilicon layer on the gate oxide layer of the PMOS region and a second polysilicon layer on the gate oxide layer of the NMOS region, the first polysilicon layer being doped with impurities comprising boron (B) and fluorine (F), and the second polysilicon layer being doped with impurities without boron (B) and fluorine (F);
performing a main heat treatment on the first and second polysilicon layers at a temperature in a range of about 400° C. to about 1200° C. in an ambient hydrogen atmosphere, thereby activating dopants in the first and second polysilicon layers and reducing and/or preventing a void caused by the fluorine (F) in the first polysilicon layer;
forming a conductive layer on the first and second polysilicon layers after the main heat treatment; and
sequentially etching the gate oxide layer, the first and second polysilicon layers and the conductive layer, thereby forming a first gate structure in the PMOS region and a second gate structure in the NMOS region, the first gate structure including a gate oxide pattern, a first polysilicon pattern and a conductive pattern sequentially stacked on the substrate in the PMOS region, and the second gate structure comprising a gate oxide pattern, a second polysilicon pattern and a conductive pattern sequentially stacked on the substrate in the NMOS region.

12. The method of claim 11, wherein the first and second polysilicon layers are doped with phosphorus (P) and/or arsenic (As).

13. The method of claim 11, wherein the first and second polysilicon layers comprises a pure polysilicon layer without impurities.

14. The method of claim 11, prior to performing the main heat treatment, further comprising performing a subsidiary heat treatment on the first and second polysilicon layers, thereby activating dopants in the first and second polysilicon layers.

15. The method of claim 14, wherein the subsidiary heat treatment is performed at a temperature of about 400° C. to about 1200° C. using one of nitrogen (N₂) gas, ammonia (NH₃) gas, argon (Ar) gas and a mixture thereof.

16. The method of claim 14, wherein the subsidiary heat treatment is performed at a temperature of about 400° C. to about 1200° C. in a vacuum state.

17. The method of claim 11, wherein the impurities comprising boron (B) and fluorine (F) comprises boron fluoride (BF₂) ions.

18. The method of claim 11, wherein the first polysilicon layer is doped with the impurities comprising boron (B) and fluorine (F) at a dose of about 10¹⁵ atoms/cm².

19. The method of claim 11, wherein the conductive layer comprises tungsten nitride (WN), tungsten (W), tantalum nitride (TaN), tantalum (Ta), tungsten silicon (WSi), cobalt silicon (CoSi₂), or combinations thereof.
